(19) United States
(12) Patent Application Publication
(10) Pub. No.: US 2007/0065959 A1
(43) Pub. Date: Mar. 22, 2007

(54) Method for manufacturing light-emitting diode

(75) Inventors: Yu-Ju Chang, Neipu Shiang (TW); Jui-Hsiang Yen, Tainan City (TW); Chi-Meng Lu, Kaohsiung Hsien (TW); Tse-Liang Ying, Tainan City (TW)

Correspondence Address: DANIEL B. SCHEIN, PH.D., ESQ., INC., P. O. BOX 68128, Virginia Beach, VA, 23471, US

(73) Assignee: Epitech Technology Corporation

(21) Appl. No.: 11/273,382

(22) Filed: Nov. 12, 2005

(30) Foreign Application Priority Data
Sep. 22, 2005 (TW) 94132908

(51) Int. Cl. H01L 21/00

(52) U.S. Cl. 438/31; 438/91

(57) ABSTRACT

A method for manufacturing a light-emitting diode is described, comprising the following steps. A substrate is provided. An illuminant epitaxial structure is formed on the substrate, wherein the illuminant epitaxial structure comprises a first conductivity type semiconductor layer, an active layer and a second conductivity type semiconductor layer stacked on the substrate in sequence, a surface of the second conductivity type semiconductor layer includes at least one epitaxial defect formed therein, and the first conductivity type semiconductor layer and the second conductivity type semiconductor layer are opposite conductivity types. Then, an insulation layer is formed to fill into the epitaxial defect in the second conductivity type semiconductor layer. A transparent electrode layer is formed on the surface of the second conductivity type semiconductor layer.

### RELATED APPLICATIONS

The present application is based on, and claims priority from, Taiwan Application Serial Number 94132908, filed Sep. 22, 2005, the disclosure of which is hereby incorporated by reference herein in its entirety.

### FIELD OF THE INVENTION

The present invention relates to a method for manufacturing a light-emitting diode, and more particularly, to a method for manufacturing a light-emitting diode of high electrostatic discharge (ESD).

### BACKGROUND OF THE INVENTION

FIG. 1 illustrates a cross-sectional view of a conventional light-emitting diode structure. Typically, in the fabrication of a light-emitting diode structure 114, a substrate 100 is provided for the growth of the material layers formed sequentially. An N-type semiconductor material layer 102 is form to cover the substrate 100 by an epitaxial method. Next, an active layer 104 is formed to cover the N-type semiconductor material layer 102 by an epitaxial method, wherein the active layer 104 may be a multiple quantum well (MQW) structure. A P-type semiconductor material layer 106 is formed on the active layer 104 by an epitaxial method, similarly. Usually, epitaxial defects are produced in a surface structure of the semiconductor material, such as epitaxial defects 108 formed in the P-type semiconductor material layer 106, due to the lattice arrangement direction of the semiconductor material. These epitaxial defects 108 may be V-shaped, such as shown in FIG. 1.

After the P-type semiconductor material layer 106 is formed, a transparent electrode layer 110 is formed to cover the P-type semiconductor material layer 106 by a deposition method. Because the surface structure of the P-type semiconductor material layer 106 includes the epitaxial defects 108, the transparent electrode layer 110 is deposited on the uneven surface of the P-type semiconductor material layer 106. Then, a metal electrode pad 112 is formed on a portion of the transparent electrode layer 110 by a deposition method. A high temperature anneal treatment is performed to complete the fabrication of a light-emitting diode structure 114, such as shown in FIG. 1.

However, because the P-type semiconductor material layer 106 has the epitaxial defects 108, the epitaxial defects 108 are filled with the material of the transparent electrode layer 110. As a result, the conductive material is close to the active layer 104, even contacts the active layer 104. When the high temperature anneal treatment is performed sequentially, the metal in the transparent electrode layer 110 and/or the metal electrode layer 112 diffuses into the active layer 104. Therefore, the electrostatic discharge protection of the light-emitting diode device may be inactive when operating at a working voltage by a low current or at a high voltage, thereby greatly reducing the reliability and operating stability of the light-emitting diode device.

### SUMMARY OF THE INVENTION

Therefore, one objective of the present invention is to provide a method for manufacturing a light-emitting diode by filling surface defects of an epitaxial layer with an insulation material before depositing a transparent electrode or a metal electrode, so as to isolate an active layer and the conductive electrode material. As a result, the electrode material can be prevented from diffusing to the active layer during the following high temperature anneal process, thereby avoiding the inactivity of the electrostatic discharge when the device is at low operating current or high operating voltage.

Another objective of the present invention is to provide a method for manufacturing a light-emitting diode by using an insulation material to repair surface defects of an epitaxial material layer, thereby improving a connection surface between an electrode layer formed sequentially and the epitaxial material layer.

Still another objective of the present invention is to provide a method for manufacturing a light-emitting diode, which can increase the efficiency of the electrostatic discharge of the light-emitting diode and can enhance the operating reliability of stability of the device.

According to the aforementioned objectives, the present invention provides a method for manufacturing a light-emitting diode, comprising the following steps. A substrate is provided. An illuminant epitaxial structure is formed on the substrate, wherein the illuminant epitaxial structure comprises a first conductivity type semiconductor layer, an active layer and a second conductivity type semiconductor layer stacked on the substrate in sequence, a surface of the second conductivity type semiconductor layer includes at least one epitaxial defect formed therein, and the first conductivity type semiconductor layer and the second conductivity type semiconductor layer are opposite conductivity types. Then, an insulation layer is formed to fill into the epitaxial defect in the second conductivity type semiconductor layer. A transparent electrode layer is formed on the surface of the second conductivity type semiconductor layer.

According to a preferred embodiment of the present invention, a material of the insulation layer may be oxide or nitride, such as silicon dioxide (SiO₂) or silicon nitride (Si₃N₄). The step of forming the insulation layer further comprises forming an insulation material layer on the surface of the second conductivity type semiconductor layer, and performing a removing step to remove the insulation material layer beyond the epitaxial defect. In the present invention, the step of forming the insulation material layer may use an electron beam evaporation method, a thermal oxidation method, a physical vapor deposition method, or a chemical vapor deposition method, and the removing step may use a wet etching process, a dry etching process or a chemical mechanical polishing process.

By filling the insulation material into the epitaxial defect, the epitaxial defect can be modified to have an insulating epitaxial surface state, thereby preventing the metal elements in the transparent electrode or the metal electrode pad formed sequentially from diffusing to the active layer, to increase the efficiency of the electrostatic discharge of the light-emitting diode and enhance the operating reliability of stability of the light-emitting diode device.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates a cross-sectional view of a conventional light-emitting diode structure; and

FIGS. 2 through 5 are schematic flow diagrams showing the process for manufacturing a light-emitting diode in accordance with a preferred embodiment of the present invention.

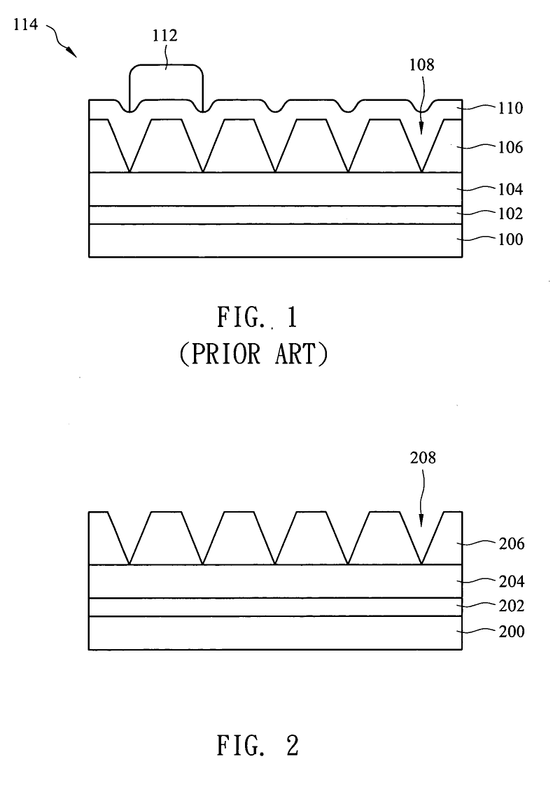

### DETAILED DESCRIPTION OF THE PREFERRED EMBODIMENT

The present invention discloses a method for manufacturing a light-emitting diode by filling an insulation material into epitaxial defects in an epitaxial material layer to isolate an active layer and a following conductive material layer, so as to improve the reliability and stability of the light-emitting diode device. In order to make the illustration of the present invention more explicit and complete, the following description is stated with reference to FIGS. 2 through 5.

FIGS. 2 through 5 are schematic flow diagrams showing the process for manufacturing a light-emitting diode in accordance with a preferred embodiment of the present invention. In the present invention, when the light-emitting diode is manufactured, a substrate 200 is provided for the growth of material layers formed thereon. A first conductivity type semiconductor layer 202 is grown on the substrate 200 by, for example, an epitaxial method. A material of the first conductivity type semiconductor layer 202 may be composed of a GaN-based or GaP-based material. Next, an active layer 204 is growth on the first conductivity type semiconductor layer 202 by, for example, an epitaxial method. A material of the active layer 204 may be composed of a GaN-based or GaP-based material, and the active layer 204 may include a multiple quantum well structure. After the growth of the active layer 204 is completed, a second conductivity type semiconductor layer 206 is grown on the active layer 204 by, for example, an epitaxial method. A material of the second conductivity type semiconductor layer 206 may be composed of a GaN-based or GaP-based material. In the present invention, the first conductivity type semiconductor layer 202 and the second conductivity type semiconductor layer 206 are opposite conductivity types. That is, when the first conductivity type semiconductor layer 202 is N-type, the second conductivity type semiconductor layer 206 is P-type; conversely, when the first conductivity type semiconductor layer 202 is P-type, the second conductivity type semiconductor layer 206 is N-type. The first conductivity type semiconductor layer 202, the active layer 204 and the second conductivity type semiconductor layer 206 constitute an illuminant epitaxial structure of the light-emitting diode. Due to the lattice arrangement direction of the semiconductor material, an epitaxial layer typically has epitaxial defects. For example, in the structure of the second conductivity type semiconductor layer 206, one or more epitaxial defects 208 may be produced. In some examples, these epitaxial defects 208 may be in V-shaped, such as shown in FIG. 2.

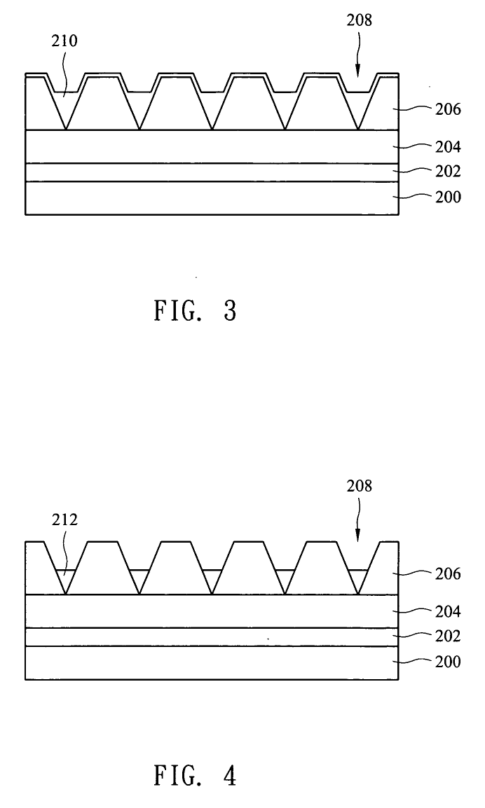

After the illuminant epitaxial structure is completed, as shown in FIG. 3, an insulation material layer 210 is formed to cover a surface of the second conductivity type semiconductor layer 206 and to fill into the epitaxial defects 208 in the surface structure of the second conductivity type semiconductor layer 206 by, for example, an electron beam evaporation method, a thermal oxidation method, a physical vapor deposition method, or a chemical vapor deposition method. In the present invention, a material of the insulation material layer 210 may be oxide, such as silicon dioxide, or nitride, such as silicon nitride. A thickness of the insulation material layer 210 is preferably between about 100 Å and about 5000 Å.

Then, a removing step is performed on the insulation material layer 210 to remove a portion of the insulation material layer 210 and remain the insulation material layer 210 within the epitaxial defects 208, such as shown in FIG. 4. In a preferred embodiment of the present invention, the removing step may include an etch-back process or a chemical mechanical polishing process. The etch-back process may use a dry etching technique or a wet-etching technique. In the etch-back process, a high selectivity etchant and a high load effected are applied to perform an appropriate over etching, so as to completely remove the insulation material layer 210 on the surface of the second conductivity type semiconductor layer 206 beyond the epitaxial defects 208 and form an insulation layer 212 in the epitaxial defects 208 to insulate the active layer 204 and a conductive material deposited sequentially. When the wet-etching technique is applied, an etchane, such as NH₄F BOE or HF, is used. When the dry-etching technique is applied, an inductively coupled plasma etcher may be used to perform an inductively coupled plasma etch, or a reactive ion etcher may be used to perform a reactive ion etch. When the chemical mechanical polishing process is applied, an end point detection method is used to monitor the polishing process to prevent the excessive polishing phenomenon from occurring and to perform an appropriate over polishing treatment when reaching the polishing end point, so as to ensure that no insulation material layer 210 remains on the surface of the second conductivity type semiconductor layer 206 except the epitaxial defects 208.

One feature of the present invention is that an insulation material is filled into epitaxial defects of an epitaxial structure after the illuminant epitaxial structure of the light-emitting diode is completed, thereby can effectively isolate the active layer and the conductive material formed sequentially to enhance the electrical stability of the device.

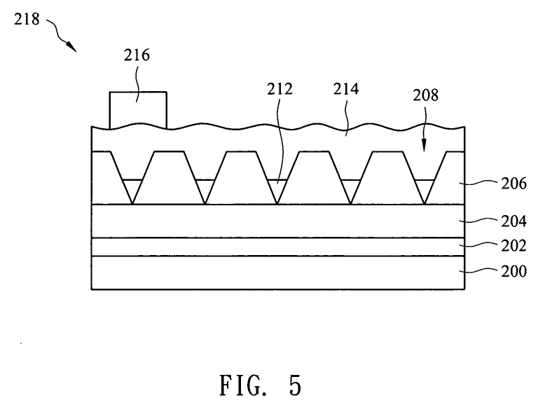

After filling the insulation layer 212 into the epitaxial defects 208, a transparent electrode layer 214 is formed to cover the surface of the second conductivity type semiconductor layer 206, to fill into the epitaxial defects 208 and to cover the insulation layer 212 by, for example, a chemical vapor deposition method. A material of the transparent electrode layer 214 is, for example, ITO or ZnO. Because the insulation layer 212 has made up a portion of the epitaxial defects 208, the transparent electrode layer 214 can be formed on the surface smoother than that in the prior art. Then, a metal electrode pad 216 is formed on a portion of the transparent electrode layer 214 by, for example, an evaporation method. Subsequently, a high temperature anneal treatment is performed to improve the electrical contact between the transparent electrode layer 214 and the metal electrode pad 216, and the fabrication of a light-emitting diode structure 218 is completed, such as shown in FIG. 5.

The epitaxial defects 208 of the second conductivity type semiconductor layer 206 are filled with the insulation layer 212, which can effectively block the transparent electrode layer 214 and the active layer 204. As a result, when the anneal treatment is performed, the metal elements, such as In or Sn, in the transparent electrode layer 214 or the metal elements in the metal electrode pad 216 can be prevented from diffusing into the active layer 204, thereby greatly improving the electrical quality of the light-emitting diode structure 218 to further enhance the reliability and stability of the light-emitting diode device. By blocking the metal elements in the transparent electrode layer 214 and the metal electrode pad 216 from diffusing into the active layer 204, it can avoid the inactivity of the electrostatic discharge when the light-emitting diode device is operated at low current or high voltage.

It is noteworthy that the manufacture technique of the present invention can be applied to a light-emitting diode device with a vertically conductive structure and a light-emitting diode device with a horizontally conductive structure.

According to the aforementioned description, one advantage of the present invention is that the method for manufacturing a light-emitting diode of the present invention fills surface defects of an epitaxial layer with an insulation material before depositing a transparent electrode or a metal electrode, so that an active layer and the electrode material can be effectively isolated to prevent the electrode material from diffusing to the active layer, and to avoid the inactivity of the electrostatic discharge when the light-emitting diode device is operated at low current or high voltage.

According to the aforementioned description, another advantage of the present invention is that the present method for manufacturing a light-emitting diode uses an insulation material to repair the defects in the epitaxial surface, so that the connecting surface condition between the following electrode layer and the epitaxial material layer is improved.

According to the aforementioned description, still another advantage of the present invention is that the electrical quality of the light-emitting diode can be enhanced to achieve the object of increasing the operating reliability and stability of the device with the application of the present method for manufacturing a light-emitting diode.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A method for manufacturing a light-emitting diode, comprising:
providing a substrate;
forming an illuminant epitaxial structure on the substrate, wherein the illuminant epitaxial structure comprises a first conductivity type semiconductor layer, an active layer and a second conductivity type semiconductor layer stacked on the substrate in sequence, a surface of the second conductivity type semiconductor layer includes at least one epitaxial defect, and the first conductivity type semiconductor layer and the second conductivity type semiconductor layer are opposite conductivity types;
forming an insulation layer to fill into the epitaxial defect in the second conductivity type semiconductor layer; and
forming a transparent electrode layer on the surface of the second conductivity type semiconductor layer.

2. The method for manufacturing a light-emitting diode according to claim 1, wherein materials of the first conductivity type semiconductor layer and the second conductivity type semiconductor layer are selected from the group consisting of GaN-based materials and GaP-based materials.

3. The method for manufacturing a light-emitting diode according to claim 1, wherein the active layer comprises a multiple quantum well structure, a material of the transparent electrode layer is selected from the group consisting of ITO and ZnO.

4. The method for manufacturing a light-emitting diode according to claim 1, wherein a material of the insulation layer is selected from the group consisting of oxide and nitride.

5. The method for manufacturing a light-emitting diode according to claim 1, wherein a material of the insulation layer is selected from the group consisting of silicon dioxide (SiO₂) and silicon nitride (Si₃N₄).

6. The method for manufacturing a light-emitting diode according to claim 1, wherein the step of forming the insulation layer comprises:
forming an insulation material layer on the surface of the second conductivity type semiconductor layer; and
performing a removing step to remove the insulation material layer beyond the epitaxial defect.

7. The method for manufacturing a light-emitting diode according to claim 6, wherein a thickness of the insulation material layer is between about 100 Å and about 5000 Å.

8. The method for manufacturing a light-emitting diode according to claim 6, wherein the removing step comprises a wet etching process.

9. The method for manufacturing a light-emitting diode according to claim 8, wherein the wet etching process comprises using an etchant, and the etchant includes NH₄F BOE or HF.

10. The method for manufacturing a light-emitting diode according to claim 6, wherein the removing step comprises a dry etching process.

11. The method for manufacturing a light-emitting diode according to claim 10, wherein the dry etching process uses an inductively coupled plasma etcher or a reactive ion etcher.

12. The method for manufacturing a light-emitting diode according to claim 6, wherein the removing step comprises a chemical mechanical polishing process.

13. The method for manufacturing a light-emitting diode according to claim 6, wherein the step of forming the insulation material layer uses an electron beam evaporation method, a thermal oxidation method, a physical vapor deposition method, or a chemical vapor deposition method.

14. The method for manufacturing a light-emitting diode according to claim 1, after the step of forming the transparent electrode layer further comprising:
forming a metal electrode pad on the transparent electrode layer; and
performing an anneal treatment.

15. A method for manufacturing a light-emitting diode, comprising:
providing a substrate;
forming an illuminant epitaxial structure on the substrate, wherein the illuminant epitaxial structure comprises a first conductivity type semiconductor layer, an active layer and a second conductivity type semiconductor layer stacked on the substrate in sequence, a surface of the second conductivity type semiconductor layer includes a plurality of epitaxial defects, and the first conductivity type semiconductor layer and the second conductivity type semiconductor layer are opposite conductivity types;
forming an insulation material layer covering the surface of the second conductivity type semiconductor layer and filling into the epitaxial defects;
performing a removing step to remove a portion of the insulation material layer and remain the insulation material layer within the epitaxial defects;
forming a transparent electrode layer on the surface of the second conductivity type semiconductor layer;
forming a metal electrode pad on the transparent electrode layer; and
performing an anneal step.

16. The method for manufacturing a light-emitting diode according to claim 15, wherein a material of the insulation material layer is selected from the group consisting of oxide and nitride.

17. The method for manufacturing a light-emitting diode according to claim 15, wherein a thickness of the insulation material layer is between about 100 Å and about 5000 Å.

18. The method for manufacturing a light-emitting diode according to claim 15, wherein the removing step comprises a etching process.

19. The method for manufacturing a light-emitting diode according to claim 18, wherein the etching process is a wet etching process and comprises using an etchant, and the etchant includes NH₄F BOE or HF.

20. The method for manufacturing a light-emitting diode according to claim 18, wherein the etching process is a dry etching process and uses an inductively coupled plasma etcher or a reactive ion etcher.

21. The method for manufacturing a light-emitting diode according to claim 18, wherein the etching process includes an over etching treatment.

22. The method for manufacturing a light-emitting diode according to claim 15, wherein the removing step comprising a chemical mechanical polishing process.

23. The method for manufacturing a light-emitting diode according to claim 22, wherein the chemical mechanical polishing process comprises an over polishing treatment.

24. The method for manufacturing a light-emitting diode according to claim 15, wherein the step of forming the insulation material layer uses an electron beam evaporation method, a thermal oxidation method, a physical vapor deposition method, or a chemical vapor deposition method.
